(19) United States
(12) Patent Application Publication
(10) Pub. No.: US 2025/0248062 A1
(43) Pub. Date: Jul. 31, 2025

(54) TRANSISTOR AND METHOD FOR PRODUCING SUCH A TRANSISTOR

(71) Applicant: Robert Bosch GmbH, Stuttgart (DE)

(72) Inventors: Christian Huber, Ludwigsburg (DE); Klaas Strempel, Stuttgart (DE)

(21) Appl. No.: 19/037,698

(22) Filed: Jan. 27, 2025

(30) Foreign Application Priority Data
Jan. 30, 2024 (DE) 10 2024 200 795.1

(51) Int. Cl. H10D 30/47; H01L 21/265; H01L 21/3065; H10D 30/01; H10D 62/10; H10D 62/824; H10D 64/23; H10D 64/27; H10D 84/82

(52) U.S. Cl. CPC H10D 30/478; H01L 21/26546; H01L 21/3065; H10D 30/015; H10D 30/475; H10D 30/477; H10D 62/102; H10D 62/824; H10D 64/257; H10D 64/513; H10D 84/82

(57) ABSTRACT

A transistor. The transistor includes a top side with V-shaped trenches, wherein inner V-shaped trenches are at least partially conductive, and outer V-shaped trenches are at least partially non-conductive. Methods for producing such a transistor are also described.

### FIELD

The present invention relates to a transistor and to a method for producing such a transistor.

### BACKGROUND INFORMATION

Transistors made of the semiconductor gallium nitride (GaN) offer the possibility of realizing components with low on-resistances and simultaneously high breakdown voltages.

One possible design of a GaN transistor is the so-called V-shaped gate high electron mobility transistor (VHEMT) or the trench current-aperture vertical electron transistor (Trench CAVET).

Transistors described in the related art regularly consist of a highly doped conductive current spreading layer made of gallium nitride (GaN), above which a weakly n-doped GaN drift layer is applied. Above the weakly n-doped GaN drift layer there is a p-doped GaN layer and, thereabove, an insulating aluminum gallium nitride (AlGaN) or GaN layer. The p-doped GaN layer and the insulating GaN or AlGaN layer are penetrated by V-shaped trenches over which an undoped GaN layer and an AlGaN layer extend. A two-dimensional electron gas (2DEG) forms in the region of the undoped GaN layer at the interface between the undoped GaN layer and the AlGaN layer. A p-doped GaN layer is optionally incorporated in the V-shaped trenches to ensure normally-OFF operation of the component. A gate electrode contacts the p-doped GaN layer. A source contact is connected to the 2DEG. Furthermore, a source contact area can be provided, which additionally contacts the 2DEG laterally. In that case, the lower part of the source contact can also be designed as a p-contact via which the p-layer is connected.

Without a gate voltage applied, such transistors are normally-off transistors because the 2DEG below the p-doped GaN layer is depleted. By applying a positive voltage to the gate electrode, the entire 2DEG is filled with electrons and the electrons flow from the source contact over the sidewall of the trench into the trench bottom and from there further down over the GaN drift layer and the current spreading layer into a drain electrode, which is typically attached to the backside of the substrate.

Such or similar transistor structures are described, for example, in US Patent Nos. U.S. Pat. No. 10,050,138 B2, U.S. Pat. No. 7,592,647 B2 and U.S. Pat. No. 8,729,562 B2.

The threshold voltage of the VHEMTs is largely dependent on the flank angle of the V-shaped trenches, as it influences the polarization charge at the GaN-AlGaN interface.

The trenches are structured using a dry-chemical process. Due to the process, the flank angle of the outermost trench of a structure field typically deviates from the flank angle of the other trenches. In the transistor, this angular deviation causes a shift in the threshold voltage in the region of the outer trenches. This results in an inhomogeneous current flow in the component, which in turn is problematic for the reliability and performance of the transistor.

The choice of the flank angle is a trade-off between the highest possible charge carrier density and the highest possible threshold voltage, with flat angles being advantageous for the former, while steep angles are preferable for the latter. Therefore, an angle close to 45 degrees is typically used. The angled etching flanks are achieved by a masking layer with beveled edges, which is partially consumed during the etching process to produce an angled structure of the GaN material. For example, it is suitable to use a resist mask having edges rounded by thermal flow. After the resist mask is structured using photolithography, the edges are rounded by thermal flow. The shape of the edges depends on the width of the resist bridges between the later trenches, which is why the outer edge of the surrounding resist layer deviates from the edges within the structure field. During a dry etching step, the mask is partially consumed, causing sloped flanks to form in the GaN material. The flank angle of the outer trench or trenches deviates from the flank angle within the structural field, i.e., the inner trenches.

An object of the present invention is to overcome the disadvantages described above.

### SUMMARY

The object may be achieved according to the present invention by a transistor, and methods having certain features of the present invention.

According to the present invention, a transistor is thus provided which comprises a top side with V-shaped trenches. A conductive transistor channel which can be controlled by a control electrode is formed at least partially along inner V-shaped trenches, i.e., along trenches which are surrounded laterally, in particular on all sides and/or on two opposite sides, by further trenches. The inner V-shaped trenches are therefore designed to be at least partially conductive or have a conductive region. Outer V-shaped trenches, i.e., trenches which are not bordered by another trench on at least one side, are designed to be at least partially non-conductive, i.e., such that they prevent a current flow. The outer V-shaped trenches are therefore at least partially free of a conductive transistor channel which can be controlled by a control electrode.

According to the present invention, a transistor is provided with V-shaped trenches in such a way that the outer V-shaped trenches or at least their outer flanks do not contribute to current flow. That is, the transistor according to the present invention includes a plurality of identical unit cells arranged in a row, each of which has a V-shaped trench, wherein at least the outermost unit cells differ from the inner unit cells in that they do not contribute to current flow or in that they contribute to current flow only in one, in particular inner, partial region, thus forming a conductive transistor channel which can be controlled by a control electrode, at most in one inner partial region.

This prevents process-related deviations in the flank angle of the outer V-shaped trenches from negatively affecting the electrical properties of the transistor. In addition, the transistor according to the present invention makes it possible to use the outer V-shaped trenches as part of an edge termination strategy.

For example, the conductive transistor channel, which can be controlled by a control electrode, forms the conductive region.

The transistor channel is, for example, an HEMT channel.

In a preferred embodiment of the transistor according to the present invention, the inner V-shaped trenches are designed to be completely conductive or only non-conductive at the ends and otherwise conductive.

In an exemplary embodiment of the transistor according to the present invention, the outer V-shaped trenches are completely non-conductive or only an outer flank of each of the outer V-shaped trenches is non-conductive.

The transistor is, for example, an HEMT, in particular a VHEMT.

The transistor can be a vertical transistor, i.e., can have a plate-like shape.

Alternatively, according to an example embodiment of the present invention, the transistor can be a quasi-vertical transistor, i.e., a transistor which is contacted from above at a lateral trench.

For example, the lateral trench laterally adjoins an active transistor region of the transistor.

The trench is, for example, deeply etched.

In a preferred embodiment of the present invention, the transistor according to the present invention comprises a substrate layer, a highly doped conductive GaN current spreading layer arranged on the substrate layer, a weakly n-doped GaN drift layer arranged on the highly doped conductive GaN current spreading layer, a p-doped GaN layer arranged on the weakly n-doped GaN drift layer and an insulating GaN or AlGaN layer arranged on the p-doped GaN layer.

The V-shaped trenches can extend through, in particular interrupt, the p-doped GaN layer and the insulating GaN or AlGaN layer.

In a preferred embodiment of the transistor according to the present invention, the V-shaped trenches each extend linearly or form a closed hexagonal shape.

The present invention further relates to a method for producing the transistor described above, comprising deep etching of the top side of the transistor to form the V-shaped trenches, at least partially, in particular completely, covering the outer V-shaped trenches and/or end regions of the inner V-shaped trenches with an amorphous protective layer, epitaxially overgrowing the top side of the transistor, in particular the inner V-shaped trenches, with a GaN layer, in particular a low-doped or undoped GaN layer, an insulating GaN or AlGaN layer and optionally a p-doped GaN cover layer, and subsequently removing the amorphous protective layer by etching.

In a preferred embodiment of the method according to the present invention, the amorphous protective layer is an oxide layer or nitride layer, in particular consisting of silicon dioxide (SiO₂) or silicon nitride (SIN).

In an exemplary embodiment of the method according to the present invention, the amorphous protective layer is wet-chemically etched.

The present invention further relates to another method for producing the transistor described above, comprising epitaxially overgrowing the top side of the transistor, in particular the inner V-shaped trenches, with a GaN layer, in particular a low-doped or undoped GaN layer, an insulating GaN or AlGaN layer and optionally a p-doped GaN cover layer, covering the inner V-shaped trenches and/or a partial region of the outer V-shaped trenches with a protective layer for protection against damage to produce at least one uncovered region, removing at least the top layer of the transistor in the uncovered region, in particular at least the insulating GaN or AlGaN layer, by etching, or destroying the conductivity of the transistor in the uncovered region by means of ion implantation and then removing the protective layer.

During the covering process, the inner V-shaped trenches are completely covered, for example.

Alternatively, according to an example embodiment of the present invention, the inner V-shaped trenches can be covered only in a central region, while end regions of the inner V-shaped trenches adjoining the central region remain uncovered.

The outer V-shaped trenches can be partially covered during the covering process.

For example, inner walls of the outer V-shaped trenches and/or a partial region of the outer V-shaped trenches which adjoin inner trenches are covered during the covering process.

Etching can be a dry-chemical etching.

For example, inductively coupled plasma reactive ion etching (ICP RIE) is applied, in particular using chlorine-containing process gases.

In one exemplary embodiment of the further method according to the present invention, the protective layer comprises a lacquer, a metal and/or an amorphous material, in particular a nitride or an oxide, in particular SiO₂, or is formed therefrom.

In a preferred embodiment of the further method according to the present invention, nitrogen and/or argon ions are used during ion implantation.

Further advantages can be found in the following description of exemplary embodiments and the rest of the disclosure herein.

### BRIEF DESCRIPTION OF THE DRAWINGS

The present invention is explained in more detail below with reference to exemplary embodiments shown in the figures.

FIG. 1 shows a plan view of a schematic representation of a first transistor according to an example embodiment of the present invention together with a source contact, source electrodes and a gate contact.

FIG. 2 shows an edge region of a sectional view through the first transistor of FIG. 1 in an intermediate state during production.

FIG. 3 shows an edge region of a sectional view through a second transistor according to an example embodiment of the present invention in an intermediate state during production.

FIG. 4 shows an inner region of a sectional view through the second transistor according to the present invention in a finished state.

FIG. 5 shows an edge region of a sectional view through a third transistor according to an example embodiment of the present invention in an intermediate state during production.

FIG. 6 shows a plan view of a fourth transistor according to an example embodiment of the present invention together with source electrodes.

### DETAILED DESCRIPTION OF EXAMPLE EMBODIMENTS

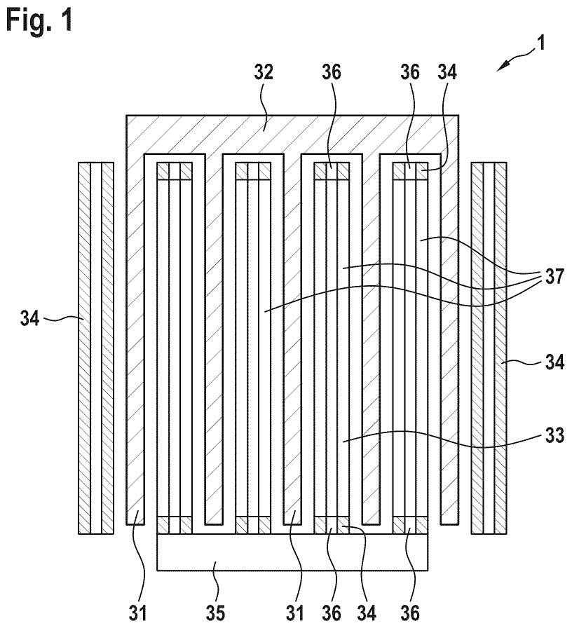

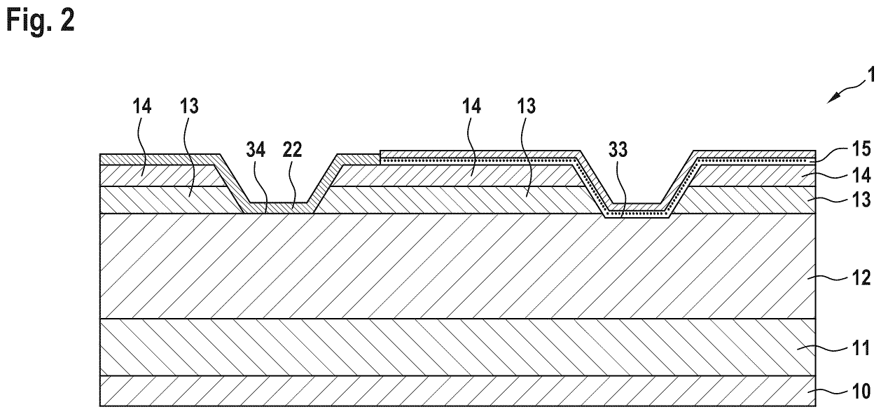

FIGS. 1 and 2 show a first transistor 1 according to the present invention. Transistor 1 is a GaN-based VHEMT. The transistor 1 is plate-shaped.

Source electrodes 31 are arranged on surrounding plateaus, which source electrodes have a planar grown 2DEG-AlGaN-GaN layer stack. Furthermore, contact pads are provided for supplying a source contact 32 and a gate contact 35 (see FIG. 1).

As shown in FIG. 2, the transistor 1 has a highly doped conductive GaN current spreading layer 11, above which a weakly n-doped GaN drift layer 12 is applied. On the GaN drift layer 12 there is a p-doped GaN layer 13, on which in turn an insulating GaN or AlGaN layer 14 is arranged.

The p-doped GaN layer 13 and the insulating GaN or AlGaN layer 14 are penetrated by V-shaped trenches 33 and 34. The V-shaped trenches 33 and 34 extend parallel to each other. The inner V-shaped trenches 33 contribute to current flow of the VHEMT, while the outer V-shaped trenches 34 prevent current flow.

The inner V-shaped trenches 33, i.e., trenches which are laterally surrounded by further V-shaped trenches 33, 34, comprise an electrically conductive region 37 which is adjoined at each end in the longitudinal extension of the trench by a non-conductive region 36, i.e., a region which prevents current flow.

The electrically conductive regions 37 are conductive transistor channels formed along the V-shaped trenches 33 and controllable by a control electrode.

The outer V-shaped trenches 34 are not adjoined by a further V-shaped trench 33, 34 at least on one side. The outer V-shaped trenches 34 are arranged, in particular in a plan view, in an edge region of the transistor 1.

An undoped GaN layer 15 and an AlGaN layer 16 extend in a vertically inner region of the transistor 1 which comprises the electrically conductive regions 37 of the inner V-shaped trenches 33. The 2DEG forms in the region of the undoped GaN layer 15 at the interface between the undoped GaN layer 15 and the AlGaN layer 16.

In the electrically conductive regions 37 of the inner trenches 33, a p-doped GaN layer can moreover be applied on the AlGaN layer 16 in order to ensure normally-OFF operation. The gate electrode 18 can contact the p-doped GaN layer.

The design of the non-conductive regions 36 of the inner V-shaped trenches 33 corresponds to the design of the outer V-shaped trenches 34.

The outer V-shaped trenches 34 and the non-conductive regions 36 of the inner V-shaped trenches 33 are covered with an amorphous protective layer 22 before overgrowth with the undoped GaN layer 15, the AlGaN layer 16 and optionally the p-doped GaN layer. The amorphous protective layer 22 prevents epitaxial growth in the covered regions.

Suitable amorphous protective layers 22 are in particular oxide and nitride layers, preferably made of SiO₂ or SiN. Using the amorphous protective layer 22 for spatially limiting epitaxial growth is conventionally used, among other things, in selective growth processes for three-dimensional GaN nanostructures (selective area growth).

The amorphous protective layer 22 suppresses the nucleation of gallium and nitrogen atoms and/or enhances the desorption of atoms adsorbed on the mask surface as well as their lateral diffusion. As a result, no 2DEG is formed in the outer V-shaped trenches 34 and the non-conductive regions 36 of the inner V-shaped trenches 33, so that a contribution to current flow in these regions is prevented, i.e., they are non-conductive.

The amorphous protective layer 22 is removed by etching after application of the undoped GaN layer 15, the AlGaN layer 16 and optionally the p-doped GaN layer. Wet-chemical etching is particularly suitable for this purpose.

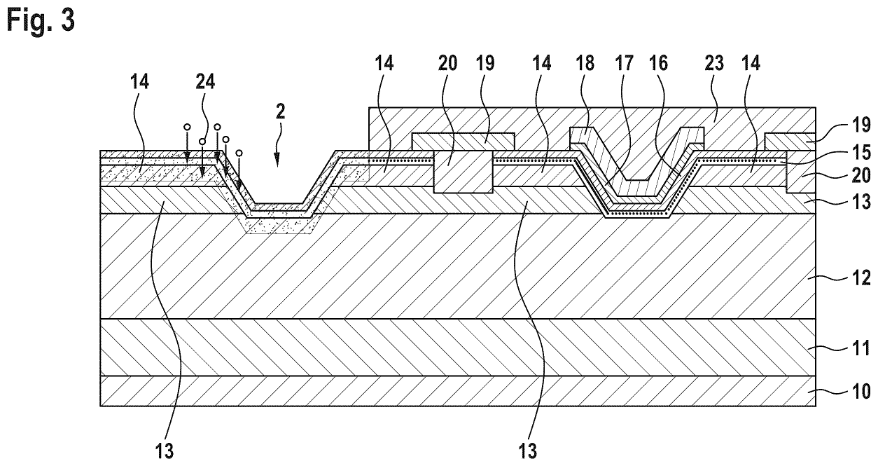

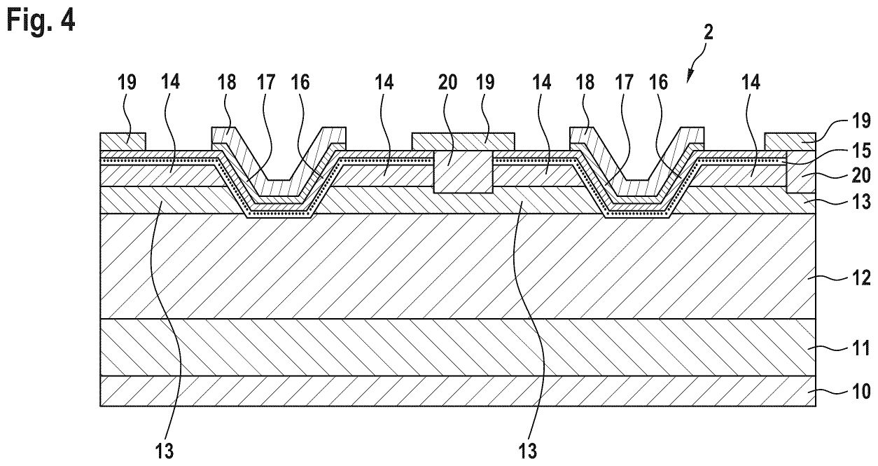

FIGS. 3 and 4 show a second transistor 2 according to the present invention.

The second transistor 2 substantially corresponds to the first transistor 1 shown in FIGS. 1 and 2. Therefore, only the distinguishing features will be explained below. As regards the further features, reference is made to the above statements concerning the first transistor 1, wherein, in FIGS. 3 and 4, elements which correspond to elements of the first transistor 1 are provided with the same reference signs used in FIGS. 1 and 2.

The second transistor 2 differs from the first transistor 1 in that the outer V-shaped trenches 34 and the non-conductive end regions 36 of the inner V-shaped trenches 33 are also overgrown with the undoped GaN layer 15 and the AlGaN layer 16 and optionally with the p-doped GaN layer 17. During production of the second transistor 2, no amorphous protective layer is hence used during epitaxial overgrowth.

The conductivity of the outer trenches 34 and the non-conductive end regions 36 of the inner trenches 33 is destroyed locally by ion implantation after epitaxial overgrowth, so that damaged regions 24 are produced. No 2DEG is formed in the damaged regions 24.

The timing of the implantation step in the process sequence is variable. For example, implantation occurs after completion of gate and source contacts.

In order to limit damage to the semiconductor material by the ion bombardment of the conductive region 37 of the inner trenches 33, the conductive region 37 is covered with a protective mask 23 or protective layer which prevents the ions from penetrating the covered region. The protective mask 23 is removed after ion implantation.

Suitable protective masks include lacquer, metal or amorphous layers, in particular lacquer, nitrides or oxides, especially SiN or SiO₂.

Examples of ions which can cause damage include nitrogen or argon ions.

In the electrically conductive regions 37 of the inner V-shaped trenches 33, a p-doped GaN layer 17 is applied to the AlGaN layer 16 in order to ensure a normally-OFF operation of the component. The gate electrode 18 is in contact with the p-doped GaN layer 17.

The source contact 19 contacts the 2DEG from above.

Furthermore, a source contact area 20 is optionally provided, which additionally contacts the 2DEG from the side. The lower part of the source contact area 20 is designed as a p-contact via which the p-doped GaN layer 13 is connected.

A drain electrode 21 is located on the backside of the substrate 10.

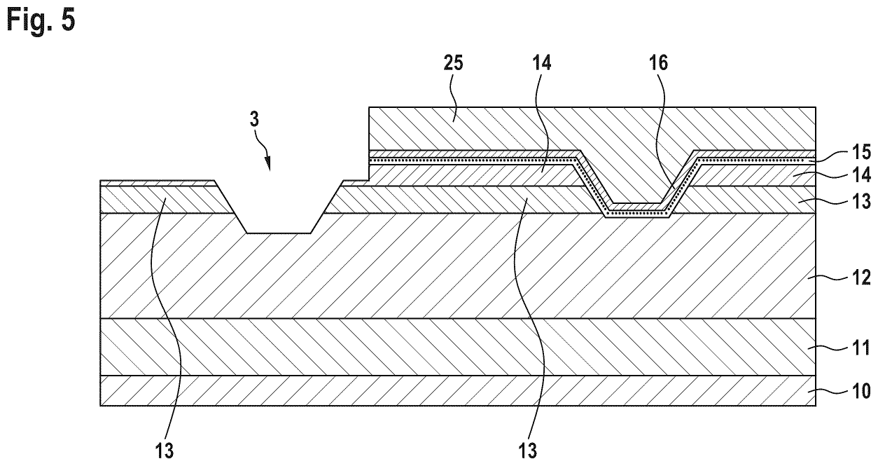

FIG. 5 shows a third transistor 3 according to the present invention. The third transistor 3 substantially corresponds to the first transistor 1 shown in FIGS. 1 and 2. Therefore, only the distinguishing features will be explained below. As regards the further features, reference is made to the above description regarding the first transistor 1. Elements of the third transistor 3 shown in FIG. 5, which correspond to elements of the first transistor 1, are provided with the same reference signs.

In order to make the outer V-shaped trenches 34 and the non-conductive end regions 36 of the inner V-shaped trenches 33 non-conductive, the upper semiconductor layers, in particular the p-doped GaN layer 17 (not shown), the AlGaN layer 16, the undoped GaN layer 15, the AlGaN layer 14, the p-doped GaN layer 13 and/or the GaN drift layer 12 in the region of the outer V-shaped trenches 34 and in the region of the non-conductive end regions 36 of the inner V-shaped trenches 33 are partially removed locally in an etching step, but at least until the AlGaN layer 16 is completely removed, so that no 2DEG is formed in these regions.

Etching is carried out, for example, by means of dry-chemical etching, in particular by means of inductively coupled plasma reactive ion etching (ICP RIE), preferably using Cl-containing process gases.

In order to prevent damage to the conductive regions 37 of the inner V-shaped trenches 33 as a result of the etching process, they are covered with a protective mask 25 or protective layer before etching.

Possible materials for the protective mask include lacquers, metals or amorphous materials, in particular nitrides or oxides, especially SiO₂.

Etching is preferably carried out either directly after overgrowth or after processing of the source contact 19.

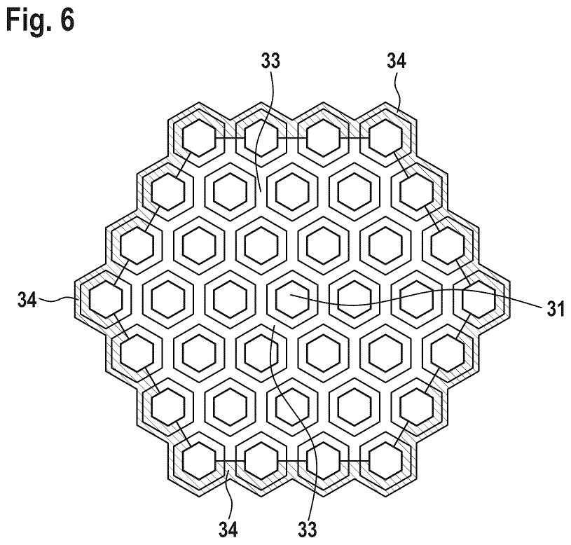

FIG. 6 shows a fourth transistor 4 according to the present invention.

The fourth transistor 4 substantially corresponds to the first transistor 1 shown in FIGS. 1 and 2. Therefore, only the distinguishing features will be explained below. As regards the further features, reference is made to the above statements concerning the first transistor 1, wherein, in FIG. 6, elements which correspond to elements of the first transistor 1 are provided with the same reference signs used in FIGS. 1 and 2.

The fourth transistor 4 differs from the first transistor 1 shown in FIG. 1 in that the V-shaped trenches 33, 34 are not linear and extend parallel to each other, but each form a hexagonal shape in plan view.

The inner V-shaped trenches 33 of the fourth transistor 4 are completely conductive, while the outer V-shaped trenches 34 have a conductive region and a non-conductive region. The non-conductive regions are arranged such that together they form a non-conductive outer region of the transistor 4.

The specific design of the non-conductive regions and conductive regions can correspond to the embodiments shown in the above described figures.

The embodiments described and shown in the figures are merely exemplary. Different embodiments can be combined with each other completely or with respect to individual features. An embodiment can also be supplemented by features of another embodiment. Furthermore, described method steps can be repeated and carried out in a different order than described.

1-14. (canceled)

15. A transistor, comprising:
a top side with V-shaped trenches, wherein a conductive transistor channel controllable by a control electrode is formed at least partially along inner V-shaped trenches of the V-shaped trenches;
wherein outer V-shaped trenches of the V-shaped trenches are at least partially non-conductive.

16. The transistor according to claim 15, wherein: (i) the inner V-shaped trenches are completely conductive, or (ii) only end regions of the inner V-shaped trenches are non-conductive.

17. The transistor according to claim 15, wherein: (i) the outer V-shaped trenches are completely non-conductive, or, (ii) only outer flanks of the outer V-shaped trenches are non-conductive.

18. The transistor according to claim 15, further comprisng:
a substrate layer;
a highly doped conductive gallium nitride current spreading layer;
a weakly n-doped gallium nitride drift layer; and
(i) a p-doped gallium nitride layer and/or (ii) an insulating gallium nitride or aluminum gallium nitride layer.

19. The transistor according to claim 18, wherein the V-shaped trenches extend through the p-doped gallium nitride layer and/or through the insulating gallium nitride or aluminum gallium nitride layer.

20. The transistor according to claim 15, wherein the V-shaped trenches each extend linearly or each form a closed hexagonal shape.

21. The transistor according to claim 15, wherein the transistor is a vertical gallium nitride transistor.

22. A method for producing a transistor, comprising the following steps:
i) deep etching a top side of the transistor to form V-shaped trenches;
ii) at least partially covering, with an amorphous protective layer, outer V-shaped trenches of the V-shaped trenches and/or end regions of inner V-shaped trenches of the V-shaped trenches;
iii) epitaxially overgrowing the top side of the transistor with a gallium nitride layer and an insulating gallium nitride or aluminum gallium nitride layer; and
iv) removing the amorphous protective layer by etching.

23. The method according to claim 22, wherein, in the produced transistor:
a conductive transistor channel controllable by a control electrode is formed at least partially along the inner V-shaped trenches; and
the outer V-shaped trenches are at least partially non-conductive.

24. The method according to claim 22, wherein the amorphous protective layer is an oxide or a nitride layer, including silicon dioxide or silicon nitride.

25. The method according to claim 22, wherein wet-chemical etching is carried out in step iv.

26. A method for producing a transistor, the method comprising the following steps:
v) epitaxially overgrowing a top side of the transistor with a gallium nitride layer and an insulating gallium nitride or aluminum gallium nitride layer;
vi) at least partially covering inner V-shaped trenches and/or inner flanks of outer V-shaped trenches with a protective layer to produce at least one uncovered region;
vii) removing at least a top layer in an uncovered region by etching or destroying the conductivity of the transistor in the uncovered region using ion implantation; and
viii) removing the protective layer.

27. The method according to claim 26, wherein, in the produced transistor:
a conductive transistor channel controllable by a control electrode is formed at least partially along the inner V-shaped trenches; and
the outer V-shaped trenches are at least partially non-conductive.

28. The method according to claim 26, wherein in the step vii, dry-chemical etching is carried out by inductively coupled plasma reactive ion etching using chlorine-containing process gases.

29. The method according to claim 26, wherein the protective layer includes a lacquer and/or a metal and/or an amorphous material including a nitride and/or an oxide.

30. The method according to claim 26, wherein nitrogen ions and/or argon ions are used during ion implantation.
